(19) United States
(12) Patent Application Publication
(10) Pub. No.: US 2017/0179413 A1
(43) Pub. Date: Jun. 22, 2017

(54) TRANSISTOR AND MANUFACTURING METHOD OF TRANSISTOR

(71) Applicant: FUJIFILM CORPORATION, Tokyo (JP)

(72) Inventors: Yoshihisa USAMI, Kanagawa (JP); Yoshiki MAEHARA, Kanagawa (JP); Takahiko ICHIKI, Kanagawa (JP)

(73) Assignee: FUJIFILM CORPORATION, Tokyo (JP)

(21) Appl. No.: 15/454,247

(22) Filed: Mar. 9, 2017

Related U.S. Application Data
(63) Continuation of application No. PCT/JP2015/071649, filed on Jul. 30, 2015.

(30) Foreign Application Priority Data
Sep. 18, 2014 (JP) 2014-190054

(51) Int. Cl. H01L 51/05; H01L 51/10

(52) U.S. Cl. CPC H01L 51/0529; H01L 51/105; H01L 51/0545

(57) ABSTRACT

A transistor and a manufacturing method of a transistor which prevents a decrease in mobility, prevents a decrease in a withstand voltage of the insulating layer, and prevents a short circuit between a gate electrode and a semiconductor layer due to curvature. A substrate having insulating properties, a source electrode and a drain electrode disposed in a surface direction of a main surface of the substrate by being separated from each other, a gate electrode disposed between the source electrode and the drain electrode in the surface direction of the substrate, a semiconductor layer disposed in contact with the source electrode and the drain electrode, and an insulating film disposed between the gate electrode and the semiconductor layer in a direction perpendicular to the main surface of the substrate are included, and a gap region is formed between the semiconductor layer and the insulating film.

### CROSS-REFERENCE TO RELATED APPLICATIONS

This application is a Continuation of PCT International Application No. PCT/JP2015/071649 filed on Jul. 30, 2015, which claims priority under 35 U.S.C. §119(a) to Japanese Patent Application No. 2014-190054 filed on Sep. 18, 2014. The above application is hereby expressly incorporated by reference, in its entirety, into the present application.

### BACKGROUND OF THE INVENTION

1. Field of the Invention

The present invention relates to a transistor and a manufacturing method of a transistor.

2. Description of the Related Art

A thin film transistor (TFT) has been used in a display, a solid image pickup element, a transistor circuit, a radio frequency identifier (RFID), and the like. In particular, it is expected that a TFT using a coating type semiconductor can prepare a large-area TFT at a low cost by using a printing step together.

A structure of a TFT includes various forms according to an arrangement position of a gate electrode, and a source electrode and a drain electrode. In particular, in a bottom gate and bottom contact structure in which both of the gate electrode, and the source electrode and the drain electrode are arranged on an underlayer of a semiconductor layer, an electrode or an insulating film can be formed first on a substrate, and thus, the bottom gate and bottom contact structure becomes a structure in which productivity is high without deterioration in properties of a semiconductor due to a high temperature process or a solution process.

A TFT of the related art having a bottom gate and bottom contact structure is prepared by the following processes.

First, a gate electrode is formed on a smooth substrate. The gate electrode can be formed as an electrode having a desired pattern by photolithography in which film formation is performed with respect to a low resistance metal such as silver, gold, and aluminum, a pattern is formed by performing coating, exposure, and development with respect to a photoresist, and an unnecessary metal is removed by etching. In addition, an unnecessary portion is directly irradiated with laser without using a photoresist, and an unnecessary metal is removed by ablation, and thus, a gate electrode having a desired pattern can be formed. Alternatively, as described in JP2007-129007A, a liquid-like conductive material such as a silver nano ink is formed in a desired pattern by printing, and a gate electrode can be formed by a heat treatment or the like.

Next, an insulating film is formed on the substrate on which the gate electrode is formed. The insulating film is a dense film of an inorganic material such as SiOx or AlOx, and can be formed by vapor phase film deposition such as sputtering, a chemical vapor phase deposition (CVD) method, and an atomic layer deposition (ALD) method. Alternatively, the insulating film can be formed by attaching the organic material onto the substrate by coating or printing, and by curing the organic material attached onto the substrate with light or heat.

In addition, in a case where a circuit is formed of a plurality of TFT's, it is necessary that the insulating film includes a through hole in order to bring a gate electrode of one element into contact with a source electrode or a drain electrode of the other element. The through hole can be formed by performing photolithography or laser ablation with respect to the insulating film formed on the entire surface. Alternatively, it is also possible that a photosensitive insulating film is formed, and is patterned by exposure, and both a negative film in which an exposed portion is dissolved and a positive film in which an unexposed portion is dissolved can be used.

Further, a source electrode and a drain electrode are formed on the insulating film. A formation method can be performed by the same method as that of the gate electrode. In a case where a circuit is prepared by connecting the source electrode or the drain electrode to the gate electrode, connect wiring with respect to the gate electrode is formed in a step of forming the source electrode and the drain electrode.

After that, a semiconductor is formed on the formed electrode, and is patterned, and as necessary, a protective film or the like is formed, and thus, a TFT is prepared.

Thus, in the TFT of the related art having a bottom gate and bottom contact structure, the semiconductor is formed on the insulating film.

Here, in a case where the semiconductor is formed on the insulating film, a channel is formed on the interface of the semiconductor on the insulating film side. However, the insulating film has a substance or a structure which inhibits charge movement, and thus, mobility decreases. In addition, in a case where an organic semiconductor is formed by coating, crystals are disordered according to the shape or the substance of the surface of the insulating film, and thus, the mobility decreases. In addition, foreign substances are mixed in between the semiconductor and the insulating film, and the charge movement is inhibited, or the crystals of the organic semiconductor are disordered, and thus, the mobility decreases.

In contrast, in JP2013-38127A, an air gap type organic transistor including a pair of insulating pedestals which are arranged on a substrate by being spaced from each other and respectively form a pedestal-like flat surface, a source electrode disposed on one pedestal-like flat surface, a drain electrode disposed on the other pedestal-like flat surface, a gate electrode disposed on the substrate between the pair of pedestals, and an organic semiconductor layer disposed in contact with upper surfaces of the source electrode and the drain electrode, in which the gate electrode and a lower surface of the organic semiconductor layer face to each other in a vertical direction with a gap region interposed therebetween, is disclosed.

The air gap type organic transistor has a structure in which the gap region (a space) between the gate electrode and the lower surface of the organic semiconductor layer is used as an insulating layer. Accordingly, it is disclosed that a decrease in mobility due to the shape or the substance of the surface of the insulating film can be prevented.

### SUMMARY OF THE INVENTION

However, a dielectric breakdown voltage of an organic insulating material or an inorganic insulating material is several MV/cm, whereas a dielectric breakdown voltage of air is approximately 0.03 MV/cm. For this reason, in a configuration where air is used as an insulating layer by disposing a gap region, a withstand voltage decreases.

In addition, a TFT circuit is also required to have flexibility in a case of being used in a flexible display.

However, in a case of the air gap type organic transistor, the gap region is formed between the gate electrode and the semiconductor layer, and thus, a short circuit occurs between the gate electrode and the semiconductor layer at the time of being curved.

In addition, even in a case where the gate electrode and the semiconductor layer are not curved, the substrate or the semiconductor layer is bent in a case where thermal expansion coefficients of the semiconductor layer and the substrate are different from each other, and the gate electrode is in contact with the semiconductor layer, and thus, a short circuit occurs between the gate electrode and the semiconductor layer.

The present invention has been made for solving such problems of the technology of the related art, and an object of the present invention is to provide a transistor and a manufacturing method of a transistor in which it is possible to prevent a decrease in mobility due to the shape or the substances of a surface of an insulating film, mixing in of foreign substances, and the like, to prevent a dielectric breakdown from occurring by preventing a decrease in a withstand voltage of the insulating layer, and to prevent a short circuit between a gate electrode and a semiconductor layer due to curvature.

As a result of intensive studies of the present inventors, it has been found that the problems described above can be solved by including a substrate having insulating properties, a source electrode and a drain electrode disposed in a surface direction of a main surface of the substrate by being separated from each other, a gate electrode disposed between the source electrode and the drain electrode in the surface direction of the substrate, a semiconductor layer disposed in contact with the source electrode and the drain electrode, and an insulating film disposed between the gate electrode and the semiconductor layer in a direction perpendicular to the main surface of the substrate, and by forming a gap region between the semiconductor layer and the insulating film.

That is, it has been found that the object described above can be attained by the following configurations.

(1) A transistor, comprising: a substrate having insulating properties; a source electrode and a drain electrode disposed in a surface direction of a main surface of the substrate by being separated from each other; a gate electrode disposed between the source electrode and the drain electrode in the surface direction of the substrate; a semiconductor layer disposed in contact with the source electrode and the drain electrode; and an insulating film disposed between the gate electrode and the semiconductor layer in a direction perpendicular to the main surface of the substrate, in which a gap region is formed between the semiconductor layer and the insulating film.

(2) The transistor according to (1), in which the gate electrode is formed on the substrate, the insulating film is formed to cover at least a part of the substrate and the gate electrode, the source electrode and the drain electrode are formed on the insulating film, and the semiconductor layer is disposed to be in contact with upper surfaces of the source electrode and the drain electrode.

(3) The transistor according to (1) or (2), in which the gap region is filled with at least one of a gas or a liquid.

(4) The transistor according to (1) or (2), in which the gap region is filled with a liquid having insulating properties.

(5) The transistor according to (1) or (2), in which the gap region is in vacuum.

(6) The transistor according to any one of (1) to (5), in which a ratio of a thickness of the insulating film to a height of the gap region is 0.01 to 100, in the direction perpendicular to the main surface of the substrate.

(7) A manufacturing method of a transistor, comprising: a substrate preparing step of preparing a substrate having insulating properties; a gate electrode forming step of forming a gate electrode; a source and drain electrodes forming step of forming a source electrode and a drain electrode; an insulating film forming step of forming an insulating film; and a semiconductor layer forming step of forming a semiconductor layer, in which the insulating film is formed on the gate electrode side between the gate electrode and the semiconductor layer, and a gap region is formed between the semiconductor layer and the insulating film, in a direction perpendicular to a main surface of the substrate.

(8) A manufacturing method of a transistor, comprising: a substrate preparing step of preparing a substrate having insulating properties; a gate electrode forming step of forming a gate electrode on the substrate; an insulating film forming step of forming an insulating film to cover at least a part of the substrate and the gate electrode; a source and drain electrodes forming step of forming a source electrode and a drain electrode by separating the source electrode and the drain electrode from each other to sandwich the gate electrode therebetween in a surface direction of a main surface of the substrate such that a height from the substrate is higher than the insulating film; and a semiconductor layer forming step of forming a semiconductor layer such that the semiconductor layer is in contact with the source electrode and the drain electrode, and a gap region is formed in at least a part between the semiconductor layer and the insulating film.

(9) The manufacturing method of a transistor according to (8), in which the semiconductor layer forming step includes, a semiconductor layer preparing step of forming a semiconductor layer member on a support, and a semiconductor layer laminating step of placing the semiconductor layer member on upper surfaces of the source electrode and the drain electrode.

(10) The manufacturing method of a transistor according to (9), in which in the semiconductor layer laminating step, a surface of the semiconductor layer member on a side to be placed on the upper surfaces of the source electrode and the drain electrode is a flat surface.

According to the present invention, it is possible to prevent a decrease in mobility due to the shape or the substances of a surface of an insulating film, mixing in of foreign substances, and the like, to prevent a decrease in a withstand voltage of the insulating layer, and to prevent a short circuit between a gate electrode and a semiconductor layer due to curvature.

### BRIEF DESCRIPTION OF THE DRAWINGS

FIG. 1 is a cross-sectional view conceptually illustrating an example of a thin film transistor of the present invention.

FIG. 2A to FIG. 2D are cross-sectional views conceptually illustrating another example of the thin film transistor of the present invention.

FIG. 3A to FIG. 3D are schematic top views for illustrating a manufacturing method of the thin film transistor illustrating in FIG. 1, and FIG. 3E is a side view of FIG. 3D.

FIG. 4 is a schematic cross-sectional view of an example of an air gap type thin film transistor of the related art.

FIG. 5A to FIG. 5C are top views for illustrating a preparation method of a thin film transistor of a comparative example, and FIG. 5D is a side view of FIG. 5C.

### DESCRIPTION OF THE PREFERRED EMBODIMENTS

Hereinafter, the present invention will be described in detail.

The description of the following configuration requirements is based on representative embodiments of the present invention, but the present invention is not limited to such embodiments.

Furthermore, in the present specification, a numerical range denoted by using “to” indicates a range including numerical values before and after “to” as the lower limit value and the upper limit value.

[Transistor]

A transistor of the present invention is a transistor including a substrate having insulating properties, a source electrode and a drain electrode disposed in a surface direction of a main surface of the substrate by being separated from each other, a gate electrode disposed between the source electrode and the drain electrode in the surface direction of the substrate, a semiconductor layer disposed in contact with the source electrode and the drain electrode, and an insulating film disposed between the gate electrode and the semiconductor layer in a direction perpendicular to the main surface of the substrate, in which a gap region is formed between the semiconductor layer and the insulating film.

Furthermore, the transistor of the present invention is an electric field effect transistor, and can be preferably applied as a so-called thin film transistor (TFT).

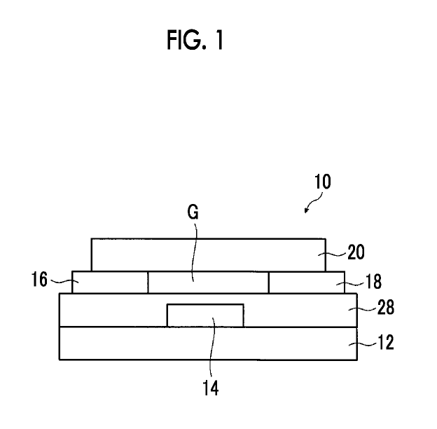

Next, the configuration of the transistor of the present invention will be described by using FIG. 1.

FIG. 1 is a schematic cross-sectional view illustrating an example of a preferred embodiment of the transistor of the present invention.

As illustrated in FIG. 1, a thin film transistor (TFT) 10 includes a substrate 12, a gate electrode 14, a source electrode 16, a drain electrode 18, a semiconductor layer 20, and an insulating film 28. In addition, the thin film transistor 10 is a so-called bottom gate and bottom contact type thin film transistor in which the gate electrode 14, and the source electrode 16 and the drain electrode 18 are formed on an underlayer of the semiconductor layer 20 (on the substrate 12 side).

The substrate 12 has insulating properties, and is a plate-like support supporting the gate electrode 14, the insulating film 28, and the like.

Furthermore, in the present invention, the substrate 12 having insulating properties is a substrate in which a current flowing through the substrate 12 is lower than a current flowing through the semiconductor layer 20 by greater than or equal to 3 digits at the time of applying a voltage to the transistor 10.

The gate electrode 14 is a member having high conductivity, and is formed on the substrate 12 in an approximate center position.

The insulating film 28 has insulating properties, and is formed to cover a main surface the substrate 12 and the gate electrode 14. In addition, an upper surface of the insulating film 28 is smoothly formed.

The source electrode 16 and the drain electrode 18 are members having high conductivity, are formed on the insulating film 28 by being separated from each other at a predetermined distance, and are arranged to sandwich the gate electrode 14 in the surface direction of the substrate. In addition, the source electrode 16 and the drain electrode 18 have approximately the same thickness.

Furthermore, a distance between the source electrode 16 and the drain electrode 18, that is, a channel length is preferably 0.1 μm to 10,000 μm, is more preferably 1 μm to 1,000 μm, and is particularly preferably 10 μm to 500 μm.

In a case where the distance between the source electrode 16 and the drain electrode 18 excessively decreases, an influence of contact resistance increases, and mobility as an element decreases, or a high accuracy is required at the time of being prepared, and thus, productivity decreases. Accordingly, it is preferable that the distance is greater than or equal to 0.1 μm from the viewpoint of preventing a decrease in the mobility and of the productivity. In contrast, in a case where the distance between the source electrode 16 and the drain electrode 18 excessively increases, a current between electrodes decreases, and thus, element properties are degraded. Accordingly, it is preferable that the distance is less than or equal to 10,000 μm from the viewpoint of the element properties.

In addition, in the following description, in a case where it is not necessary to distinguish the gate electrode 14, the source electrode 16, and the drain electrode 18 from each other, the gate electrode 14, the source electrode 16, and the drain electrode 18 will be simply referred to as an “electrode”.

The semiconductor layer 20 is an active layer formed of a semiconductor. As illustrated in FIG. 1, the semiconductor layer 20 is formed into the shape of a plate, one end portion is placed on an upper surface of the source electrode 16, and the other end portion is placed on an upper surface of the drain electrode 18.

Thus, the semiconductor layer 20 formed into the shape of a plate is placed on the source electrode 16 and the drain electrode 18, and thus, a space G is formed in a region between the semiconductor layer 20 and the insulating film 28, that is, a region between the source electrode 16 and the drain electrode 18. The space G is a gap region of the present invention.

That is, the thin film transistor 10 includes the insulating film 28 and the gap region G between the gate electrode 14 and the semiconductor layer 20 in the direction perpendicular to the main surface of the substrate 12, the insulating film 28 is disposed on the gate electrode 14 side, and the gap region is disposed on the semiconductor layer 20 side.

The gap region G may be in vacuum, or may be filled with a gas. Nitrogen, moisture vapor, helium, neon, argon, krypton, xenon, radon, and the like are exemplified as the gas. Alternatively, the gap region G may be filled with a liquid having insulating properties, such as an organic solvent. In addition, the gap region G may be filled with a mixture thereof.

It is preferable that a gas, in particular, air is used as a material filled in the gap region G from the viewpoint of reducing damage in the insulating properties, the productivity, and a surrounding environment.

The height of the gap region G is not particularly limited, but is preferably 10 nm to 10,000 nm, is more preferably 100 nm to 2,000 nm, and is particularly preferably 200 nm to 1,000 nm, from the viewpoint of the insulating properties, voltage applying properties, and the like.

As described above, the thin film transistor of the related art has a structure in which the insulating layer is in contact with the semiconductor layer, and thus, the crystals of the semiconductor layer are disordered according to the shape or the substance of the surface of the insulating layer, and thus, the mobility decreases.

In addition, in the air gap type organic transistor including the gap region between the gate electrode and the semiconductor layer, a current flows through an interface between the semiconductor layer and the gap region, and thus, it is possible to prevent a decrease in the mobility due to the shape or the substance of the surface of the insulating film. However, in the configuration where the air is used as the insulating layer by disposing the gap region, a withstand voltage decreases, and in a case where flexibility is imparted, or in a case where the substrate is curved due to a difference in the thermal expansion coefficients of the semiconductor layer and the substrate, a short circuit occurs between the gate electrode and the semiconductor layer.

In contrast, the transistor of the present invention has a configuration in which the gate electrode 14, the insulating film 28, the gap region G, and the semiconductor layer 20 are stacked in this order in the direction perpendicular to the main surface of the substrate 12. Accordingly, a current flowing between the source electrode 16 and the drain electrode 18 flows through the interface between the semiconductor layer 20 and the gap region G, and thus, it is possible to prevent a decrease in the mobility due to the shape or the substance of the surface of the insulating film, the mixing in of the foreign substances, and the like.

In addition, the insulating film 28 is disposed between the gate electrode 14 and the semiconductor layer 20, and thus, a withstand voltage between the gate electrode 14 and the semiconductor layer 20 increases, and it is possible to prevent the dielectric breakdown from occurring. In addition, even in a case where flexibility is imparted or even in a case where the substrate is curved due to the difference in the thermal expansion coefficients of the semiconductor layer and the substrate, it is possible to prevent a short circuit due to a contact between the gate electrode 14 and the semiconductor layer 20, by only bringing the semiconductor layer 20 into contact with the insulating film 28.

In addition, in the air gap type organic transistor, a distance between the gate electrode 14 and the semiconductor layer 20 is minute, and thus, it is necessary to increase a dimension accuracy such that the gate electrode 14 is not in contact with the semiconductor layer 20.

In contrast, the transistor of the present invention includes the insulating film 28 between the gate electrode 14 and the semiconductor layer 20, and thus, it is not necessary to increase the dimension accuracy compared to the air gap type transistor, and therefore, it is possible to improve a yield and to increase the productivity.

Furthermore, a ratio of the thickness of the insulating film 28 to the height of the gap region G (the thickness of the insulating film 28/the height of the gap region G) on the gate electrode 14 is preferably 0.01 to 100, is more preferably 0.05 to 20, and is particularly preferably 0.1 to 10. By setting the ratio the thickness of the insulating film 28 to the height of the gap region G to be in the range described above, it is possible to improve the insulating properties in a case where the substrate is curved.

Here, in the example illustrated in FIG. 1, a configuration is illustrated in which the present invention is applied to a bottom gate and bottom contact type thin film transistor, but the present invention is not limited thereto.

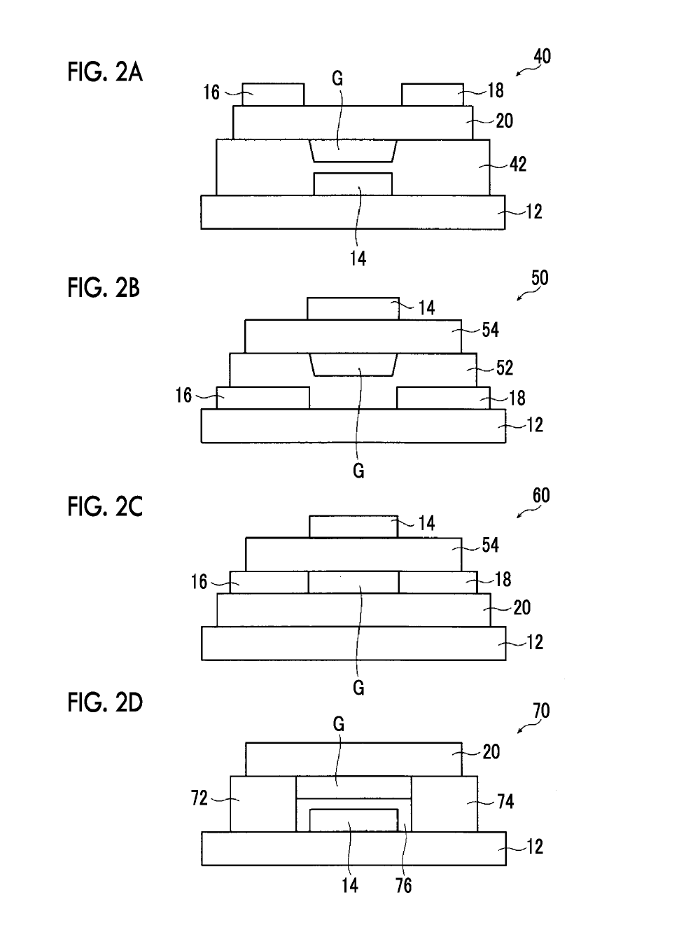

In FIG. 2A, a bottom gate and top contact type thin film transistor 40 is illustrated, in FIG. 2B, a top gate and bottom contact type thin film transistor 50 is illustrated, and in FIG. 2C, a top gate and top contact type thin film transistor 60 is illustrated.

Furthermore, in the thin film transistors illustrated in FIG. 2A to FIG. 2C, the same reference numerals are applied to the same configurations as those of the thin film transistor 10 of FIG. 1, and different portions will be mainly described in the following description.

The thin film transistor 40 illustrated in FIG. 2A includes the substrate 12, the gate electrode 14, the source electrode 16, the drain electrode 18, the semiconductor layer 20, and an insulating film 42. In addition, the thin film transistor 40 is a so-called bottom gate and top contact type thin film transistor in which the gate electrode 14 is formed on the underlayer (the substrate 12) side of the semiconductor layer 20, and the source electrode 16 and the drain electrode 18 are formed on an upper layer side of the semiconductor layer 20.

The insulating film 42 has insulating properties, and is formed to cover the main surface of the substrate 12 and the gate electrode 14. In addition, a concave portion is formed on an upper surface of the insulating film 42 in an approximate center portion. The width of the concave portion in the surface direction of the substrate is approximately identical to the width of the gate electrode 14. In the thin film transistor 40, the concave portion forms the gap region G.

The semiconductor layer 20 is formed into the shape of a plate, and is placed on the upper surface of the insulating film 42 to cover the concave portion of the insulating film 42.

The source electrode 16 and the drain electrode 18 are formed on the semiconductor layer 20 by being separated from each other at a predetermined distance. In addition, the source electrode 16 and the drain electrode 18 are arranged to sandwich the gate electrode 14 therebetween in the surface direction of the substrate.

Thus, the bottom gate and top contact type thin film transistor also has the configuration in which the gate electrode, the insulating film, the gap region, and the semiconductor layer are stacked in this order in the direction perpendicular to the main surface of the substrate, and thus, a current flows through the interface between the semiconductor layer and the gap region G, and therefore, it is possible to prevent a decrease in the mobility due to the shape or the substance of the surface of the insulating film, the mixing in of the foreign substances, and the like.

In addition, the insulating film is disposed between the gate electrode and the semiconductor layer, and thus, it is possible to increase a withstand voltage between the gate electrode and the semiconductor layer, and it is possible to prevent a short circuit due to the contact between the gate electrode and the semiconductor layer at the time of being curved.

The thin film transistor 50 illustrated in FIG. 2B includes the substrate 12, the gate electrode 14, the source electrode 16, the drain electrode 18, a semiconductor layer 52, and an insulating film 54. In addition, the thin film transistor 50 is a so-called top gate and bottom contact type thin film transistor in which the gate electrode 14 is formed on an upper layer side of the semiconductor layer 52, and the source electrode 16 and the drain electrode 18 are formed on an underlayer side of the semiconductor layer 52.

The source electrode 16 and the drain electrode 18 are formed on the substrate 12 by being separated from each other at a predetermined distance.

The semiconductor layer 52 is an active layer formed of a semiconductor, and is formed to cover the main surface of the substrate 12, and the source electrode 16 and the drain electrode 18. In addition, a concave portion is formed on the upper surface of the semiconductor layer 52 in an approximate center portion. The concave portion is formed such that the width thereof in the surface direction of the substrate is approximately identical to the distance between the source electrode 16 and the drain electrode 18. In the thin film transistor, the concave portion forms the gap region G

The insulating film 54 has insulating properties, is formed into the shape of a plate, and is placed on the upper surface of the semiconductor layer 52 to cover the concave portion of the semiconductor layer 52.

The gate electrode 14 is formed on the insulating film 54 between the source electrode 16 and the drain electrode 18 in the surface direction of the substrate.

Thus, the top gate and bottom contact type thin film transistor also has a configuration in which the semiconductor layer, the gap region, the insulating film, and the gate electrode are stacked in this order in the direction perpendicular to the main surface of the substrate, and thus, a current flows through the interface between the semiconductor layer and the gap region, and therefore, it is possible to prevent a decrease in the mobility due to the shape or the substance of the surface of the insulating film, the mixing in of the foreign substances, and the like.

In addition, the insulating film is disposed between the gate electrode and the semiconductor layer, and thus, it is possible to increase a withstand voltage between the gate electrode and the semiconductor layer, and it is possible to prevent a short circuit due to the contact between the gate electrode and the semiconductor layer at the time of being curved.

The thin film transistor 60 illustrated in FIG. 2C includes the substrate 12, the gate electrode 14, the source electrode 16, the drain electrode 18, the semiconductor layer 20, and an insulating film 54. In addition, the thin film transistor 60 is a so-called top gate and top contact type thin film transistor in which the gate electrode 14, the source electrode 16, and the drain electrode 18 are formed on the upper layer side of the semiconductor layer 20.

The semiconductor layer 20 is smoothly formed on the substrate 12.

The source electrode 16 and the drain electrode 18 are formed on the semiconductor layer 20 by being separated from each other at a predetermined distance.

The insulating film 54 has insulating properties, is formed into the shape of a plate, one end portion is placed on the upper surface of the source electrode 16, and the other end portion is placed on the upper surface of the drain electrode 18.

The gate electrode 14 is formed on the insulating film 54 between the source electrode 16 and the drain electrode 18 in the surface direction of the substrate.

In the thin film transistor 60, the insulating film 54 formed into the shape of a plate is placed on the source electrode 16 and the drain electrode 18, and thus, the gap region G is formed in a region between the semiconductor layer 20 and the insulating film 54, that is, a region between the source electrode 16 and the drain electrode 18.

Thus, the top gate and top contact type thin film transistor also has a configuration in which the semiconductor layer, the gap region, the insulating film, and the gate electrode are stacked in this order in the direction perpendicular to the main surface of the substrate, and thus, a current flows through the interface between the semiconductor layer and the gap region, and therefore, it is possible to prevent a decrease in the mobility due to the shape or the substance of the surface of the insulating film, the mixing in of the foreign substances, and the like.

In addition, the insulating film is disposed between the gate electrode and the semiconductor layer, and thus, it is possible to increase a withstand voltage between the gate electrode and the semiconductor layer, and it is possible to prevent a short circuit due to the contact between the gate electrode and the semiconductor layer at the time of being curved.

In addition, in the example illustrated in FIG. 1, a configuration is illustrated in which the source electrode 16 and the drain electrode 18 are formed on the insulating film 28 in the bottom gate and bottom contact type thin film transistor, but the present invention is not limited thereto, and a configuration may be adopted in which the source electrode and the drain electrode are formed on the substrate 12.

A thin film transistor 70 illustrated in FIG. 2D includes the substrate 12, the gate electrode 14, a source electrode 72, a drain electrode 74, the semiconductor layer 20, and an insulating film 76. The thin film transistor 70 is a bottom gate and bottom contact type thin film transistor.

The gate electrode 14 is formed on the substrate 12.

In addition, the source electrode 72 and the drain electrode 74 are members having high conductivity, and are formed on the substrate 12 by being separated from each other at a predetermined distance to sandwich the gate electrode 14 therebetween. That is, the source electrode 72, the gate electrode 14, and the drain electrode 74 are formed on the substrate 12 by being arranged in this order in the surface direction of the substrate 12.

In addition, the source electrode 72 and the drain electrode 74 are formed such that the thickness thereof is thicker than the thickness of the gate electrode 14. That is, the source electrode 72 and the drain electrode 74 are formed such that a height from the substrate 12 is higher than the gate electrode 14.

The insulating film 76 is a member having insulating properties, and is formed in a region between the source electrode 72 and the drain electrode 74 to cover the gate electrode 14.

In addition, as illustrated in FIG. 2D, the height of the surface of the insulating film 76 from the substrate 12 is lower than the height of the source electrode 72 and the drain electrode 74.

The semiconductor layer 20 is formed into the shape of a plate, one end portion is placed on an upper surface of the source electrode 72, and the other end portion is placed on an upper surface of the drain electrode 74.

The height of the surface of the insulating film 76 from the substrate 12 is lower than the height of the source electrode 72 and the drain electrode 74, and thus, the gap region G is formed the semiconductor layer 20 placed on the upper surfaces of the source electrode 72 and the drain electrode 74 and the insulating film.

Thus, even in a case of a configuration in which the source electrode 72 and the drain electrode 74 are formed on the substrate 12, the configuration is adopted in which the gate electrode, the insulating film, the gap region, and the semiconductor layer are stacked in this order in the direction perpendicular to the main surface of the substrate, and thus, a current flows through the interface between the semiconductor layer and the gap region, and therefore, it is possible to prevent a decrease in the mobility due to the shape or the substance of the surface of the insulating film, the mixing in of the foreign substances, and the like.

In addition, the insulating film is disposed between the gate electrode and the semiconductor layer, and thus, it is possible to increase a withstand voltage between the gate electrode and the semiconductor layer, and it is possible to prevent a short circuit due to the contact between the gate electrode and the semiconductor layer at the time of being curved.

In addition, it is preferable that a configuration is adopted in which the gate electrode 14, the source electrode 72, and the drain electrode 74 are formed on the same flat surface of the substrate 12, from the viewpoint of enabling the gate electrode 14, the source electrode 72, and the drain electrode 74 to be formed by printing once and the productivity to be improved by reducing the number of steps.

In addition, it is preferable that the gate electrode 14, the source electrode 72, and the drain electrode 74 are formed by printing once, from the viewpoint of enabling a positional accuracy between electrodes to be improved and reliability to be improved.

Next, the material, the dimension, and the like of each constituent of the thin film transistor of the present invention will be described.

[Substrate]

The material, the shape, the size, the structure, and the like of the substrate of the thin film transistor of the present invention are not particularly limited, but can be suitably selected according to the purpose insofar as having desired insulating properties.

A substrate formed of an inorganic material such as glass and yttria-stabilized zirconia (YSZ), a resin, a resin composite material, or the like can be used as the material of the substrate.

Among them, a substrate formed of the resin or the resin composite material is preferable from the viewpoint of lightweight, of having flexibility, and of having light transmittance.

Specifically, a substrate formed of a synthetic resin such as polybutylene terephthalate, polyethylene terephthalate, polyethylene naphthalate, polybutylene naphthalate, polystyrene, polycarbonate, polysulfone, polyether sulfone, polyarylate, allyl diglycol carbonate, polyamide, polyimide, polyamide imide, polyether imide, polybenzazole, polyphenylene sulfide, polycycloolefin, a norbornene resin, a fluorine resin such as polychlorotrifluoroethylene, a liquid crystal polymer, an acrylic resin, an epoxy resin, a silicone resin, an ionomer resin, a cyanate resin, crosslinked fumaric acid diester, cyclic polyolefin, aromatic ether, maleimide olefin, cellulose, and an episulfide compound, a substrate formed of a composite plastic material between the synthetic resin described above or the like and silicon oxide particles, a substrate formed of a composite plastic material between the synthetic resin described above or the like and metal nano particles, inorganic oxide nano particles, inorganic nitride nano particles, or the like, a substrate formed of a composite plastic material between the synthetic resin described above or the like and a carbon fiber or a carbon nano tube, a substrate formed of a composite plastic material between the synthetic resin described above or the like and a glass flake, a glass fiber, or glass beads, a substrate formed of a composite plastic material between the synthetic resin described above or the like and a clay mineral or particles having a crystal structure derived from mica, a laminated plastic substrate including a junction interface between thin glass and any one of the synthetic resins described above at least once, a substrate formed of a composite material having barrier performance which includes a junction interface at least once by alternately laminating an inorganic layer and an organic layer (the synthetic resin described above), a stainless steel substrate or a metal multilayer substrate in which stainless steel and a dissimilar metal are laminated, an aluminum substrate or an aluminum substrate with an oxide film in which a surface is subjected to an oxidization treatment (for example, an anode oxidization treatment), and thus, insulating properties of the surface are improved, and the like can be used.

Furthermore, it is preferable that a resin substrate has excellent heat resistance, excellent dimension stability, excellent solvent resistance, excellent electrical insulating properties, excellent workability, low air permeability, and low hygroscopicity. The resin substrate may include a gas barrier layer for preventing permeation of moisture or oxygen, an undercoat layer for improving smoothness of the resin substrate or adhesiveness with respect to a lower electrode, and the like.

It is preferable that the thickness of the substrate is from 50 μm to 500 μm. In a case where the thickness of the substrate is greater than or equal to 50 μm, smoothness of the substrate itself is improved. In a case where the thickness of the substrate is less than or equal to 500 μm, flexibility of the substrate itself is further improved, and the substrate is more easily used as a substrate for a flexible device. A thickness having sufficient smoothness and flexibility is different according to the material configuring the substrate, and thus, it is necessary to set the thickness according to the substrate material, and the range thereof is approximately in a range from 50 μm to 500 μm.

[Gate Electrode, Source Electrode, and Drain Electrode]

Formation materials of the gate electrode, the source electrode, and the drain electrode are not particularly limited insofar as having high conductivity, and various formation materials of a known electrode which is used in a thin film transistor of the related art can be used.

Specifically, a metal such as Ag, Au, Al, Cu, Pt, Pd, Zn, Sn, Cr, Mo, Ta, and Ti, Al—Nd, and a metal oxide such as, tin oxide, zinc oxide, indium oxide, indium tin oxide (ITO), and indium zinc oxide (IZO) can be used.

All of the gate electrode, the source electrode, and the drain electrode can be formed by a method such as printing, vacuum film formation, plating, photolithography, and laser patterning. Among them, it is preferable that the gate electrode, the source electrode, and the drain electrode are formed by the printing.

Here, the printing of the present invention includes various known printing methods such as offset printing, gravure printing, reverse printing, flexo printing, typographical printing, and screen printing. The offset printing, the flexo printing, and the reverse printing are preferable.

The formation using the printing has characteristics in that a pattern of an electrode can be formed on a substrate in one step. However, the present invention is not limited thereto, and the printing and other methods may be combined with each other. For example, a method in which a core of plating is formed by printing, and after that, an electrode which is patterned by the plating is formed, or a method in which the entire surface is subjected to printing in solid, and a pattern is directly formed by laser or the like may be used.

In the formation of the electrode using the printing, a paint (a liquid viscous material) in which fine particles of the materials described above are dispersed in a solvent is applied onto the substrate in a predetermined pattern by the printing, and is cured, and thus, each of the electrodes can be formed.

The solvent is not particularly limited, and various known solvents which are used in a case where the materials described above are used in the printing can be used.

In addition, photocuring or thermal curing is preferable as the curing of the paint, and in a case of the photocuring, it is preferable that the curing is performed by laser irradiation.

In consideration of film formability, patterning properties, conductivity, and the like, the thickness of the source electrode and the drain electrode is preferably 10 nm to 1,000 nm, and is more preferably 50 nm to 200 nm.

In addition, in consideration of the film formability, the patterning properties, the conductivity, and the like, the thickness of the gate electrode is preferably 10 nm to 1,000 nm, and is more preferably 50 nm to 200 nm.

In addition, each of the gate electrode, the source electrode, and the drain electrode may be formed of different materials, but it is preferable that each of the gate electrode, the source electrode, and the drain electrode is formed of the same material. By using the same material as the material of each of the electrodes, it is possible to improve the productivity.

Here, when each of the gate electrode, the source electrode, and the drain electrode is formed, a configuration may be adopted in which a wiring layer to be connected to each of the electrodes is integrally formed.

By simultaneously forming the wiring layer to be connected to each of the electrodes along with the formation of the electrode, it is possible to reduce the number of steps and to further improve the productivity.

In addition, a positional accuracy between the electrode and the wiring layer is further improved by simultaneously forming each of the electrodes and the wiring layer, and thus, it is possible to more reliably connect the electrode to the wiring layer and to increase reliability. In addition, accordingly, a yield becomes excellent, and the productivity can be improved.

In a case where the wiring layer and the electrode are simultaneously formed, it is preferable that a formation material of the wiring layer is identical to the material of the electrode to be connected.

[Semiconductor Layer]

A formation material of the semiconductor layer is not particularly limited, and various semiconductors which are used as an active layer in a known thin film transistor of the related art can be used.

Specifically, an oxide semiconductor such as InGaZnO, a nitride semiconductor, an inorganic semiconductor such as Si and Ge, a compound semiconductor such as GaAs, a carbon nano tube, an organic semiconductor, and the like can be used.

In the present invention, the organic semiconductor is preferably used from the viewpoint of being easily prepared, having excellent bendability, and enabling to be applied.

A pentacene derivative such as 6,13-bis(triisopropyl silyl ethynyl) pentacene (TIPS pentacene), an anthradithiophene derivative such as 5,11-bis(triethyl silyl ethynyl) anthradithiophene (TES-ADT), a benzodithiophene (BDT) derivative, a benzothienobenzothiophene (BTBT) derivative such as dioctyl benzothienobenzothiophene (C8-BTBT), a dinaphthothienothiophene (DNTT) derivative, a dinaphthobenzodithiophene (DNBDT) derivative, a 6,12-dioxaanthanthrene (perixanthenoxanthene) derivative, a naphthalene tetracarboxylic acid diimide (NTCDI) derivative, a perylene tetracarboxylic acid diimide (PTCDI) derivative, a polythiophene derivative, a poly(2,5-bis(thiophen-2-yl)thieno [3,2-b]thiophene) (PBTTT) derivative, a tetracyanoquinodimethane (TCNQ) derivative, oligothiophenes, phthalocyanines, fullerenes, a polyacetylene-based conductive polymer, a polyphenylene-based conductive polymer such as polyparaphenylene and a derivative thereof, and polyphenylene vinylene and a derivative thereof, a heterocyclic conductive polymer such as polypyrrole and a derivative thereof, polythiophene and a derivative thereof, and polyfuran and a derivative thereof, an ionic conductive polymer such as polyaniline and a derivative thereof, and the like can be used as the organic semiconductor.

A formation method of the semiconductor layer is not particularly limited, and for example, in a case of the bottom gate and bottom contact type thin film transistor 10 illustrated in FIG. 1, a semiconductor layer member is formed on a support formed of a resin, glass, or the like by a known method such as coating and transfer, and the semiconductor layer member is peeled off from the support and is placed on the upper surfaces of the source electrode 16 and the drain electrode 18, and thus, the semiconductor layer 20 can be formed. In addition, the semiconductor layer member is formed on the support, and then, the semiconductor layer member side is placed towards the source electrode 16 side and the drain electrode 18 side without peeling off the semiconductor layer member, and thus, the semiconductor layer 20 may be formed.

Similarly, in a case of the bottom gate and top contact type thin film transistor 40 illustrated in FIG. 2A, a semiconductor layer member is formed on a support formed of a resin, glass, or the like by a known method such as coating and transfer, and the semiconductor layer member is peeled off from the support or is placed on the insulating film 28 without peeling off the semiconductor layer member, and thus, the semiconductor layer 20 may be formed.

In addition, in a case of the top gate and bottom contact type thin film transistor 50 illustrated in FIG. 2B, the semiconductor layer 52 may be formed on the substrate 12 on which the source electrode 16 and the drain electrode 18 are formed, to cover at least a part of the source electrode 16 and the drain electrode 18, by a known method such as coating and transfer.

In addition, in a case of the top gate and top contact type thin film transistor 60 illustrated in FIG. 2C, the semiconductor layer 20 may be formed on the substrate 12 by a known method such as coating and transfer.

In consideration of the film formability or the like, the thickness of the semiconductor layer is preferably 1 nm to 1,000 nm, and is more preferably 10 nm to 300 nm.

[Insulating Film]

A formation material of the insulating film is not particularly limited insofar as having high insulating properties, and various formation materials of a known insulating film which is used in a thin film transistor of the related art can be used.

Specifically, compounds having insulating properties, such as SiO₂, SiNₓ, SiON, Al₂O₃, Y₂O₃, Ta₂O₅, and HfO₂, can be used. In addition, the insulating film may contain at least two of the compounds. A material containing SiO₂ is preferably used from the viewpoint of high insulating properties or the like.

The insulating film can be formed according to a method which is suitably selected from a wet method such as a printing method and a coating method, a physical method such as a vacuum vapor deposition method, a sputtering method, and an ion plating method, a chemical method such as CVD and a plasma CVD method, and the like, in consideration of suitability with respect to a material to be used.

In addition, the insulating film may be formed by being patterned into a predetermined shape by photolithography and etching.

In addition, in a case of the bottom gate and top contact type thin film transistor 40 illustrated in FIG. 2A, the insulating film may be formed by being patterned into a predetermined shape by photolithography and etching.

In addition, in a case of the top gate and bottom contact type thin film transistor 50 illustrated in FIG. 2B or the top gate and top contact type thin film transistor 60 illustrated in FIG. 2C, an insulating film member is formed on a support formed of a resin, glass, or the like into the shape of a plate by a known method such as a printing method, a coating method, a vacuum vapor deposition method, a sputtering method, an ion plating method, CVD, and a plasma CVD method, and the insulating film member is peeled off from the support and is placed on the upper surface of the semiconductor layer 52, and thus, the insulating film 54 can be formed.

The thickness of the insulating film may be suitably set according to the formation material from the viewpoint of withstand voltage properties to be required, a reduction in an applied voltage, and the like. The thickness of the insulating film is preferably from 10 nm to 10 μm, is more preferably from 50 nm to 1,000 nm, and is particularly preferably from 100 nm to 400 nm.

[Manufacturing Method of Transistor]

Next, a manufacturing method of a transistor of the present invention will be described.

The manufacturing method of a transistor of the present invention is a manufacturing method of a transistor including a substrate preparing step of preparing a substrate having insulating properties, a gate electrode forming step of forming a gate electrode, a source and drain electrodes forming step of forming a source electrode and a drain electrode, an insulating film forming step of forming an insulating film, and a semiconductor layer forming step of forming a semiconductor layer, in which the insulating film is formed on the gate electrode side between the gate electrode and the semiconductor layer, and a gap region is formed between the semiconductor layer and the insulating film, in a direction perpendicular to a main surface of the substrate.

Hereinafter, the manufacturing method of a transistor of the present invention will be described by describing a manufacturing method of a bottom gate and bottom contact type transistor.

The manufacturing method of a transistor of the present invention is a manufacturing method of a transistor including a substrate preparing step of preparing a substrate having insulating properties, a gate electrode forming step of forming a gate electrode on the substrate, an insulating film forming step of forming an insulating film to cover at least a part of the substrate and the gate electrode, a source and drain electrodes forming step of forming a source electrode and a drain electrode by separating the source electrode and the drain electrode from each other to sandwich the gate electrode therebetween in a surface direction of a main surface of the substrate such that a height from the substrate is higher than the insulating film, and a semiconductor layer forming step of forming a semiconductor layer such that the semiconductor layer is in contact with the source electrode and the drain electrode, and a gap region is formed in at least a part between the semiconductor layer and the insulating film.

In addition, the manufacturing method of a transistor of the present invention includes a semiconductor layer preparing step of forming a semiconductor layer member on a support, and a semiconductor layer laminating step of placing the semiconductor layer member on upper surfaces of the source electrode and the drain electrode in the semiconductor layer forming step, as a preferred aspect.

In the present invention, the insulating film is formed to cover the gate electrode, the source electrode and the drain electrode are formed such that the height from the substrate is higher than the insulating film, and the semiconductor layer is formed such that the semiconductor layer is in contact with the source electrode and the drain electrode, and the gap region is formed in at least a part between the semiconductor layer and the insulating film, and thus, the insulating film and the gap region are formed between the gate electrode and the semiconductor layer in the direction perpendicular to the substrate, and the semiconductor layer can be the gap region. Accordingly, a current flows through the interface between the semiconductor layer and the gap region G, and thus, it is possible to prevent a decrease in the mobility due to the shape or the substance of the surface of the insulating film, the mixing in of the foreign substances, and the like.

In addition, the insulating film is disposed between the gate electrode and the semiconductor layer, and thus, it is possible to increase a withstand voltage between the gate electrode and the semiconductor layer, and it is possible to prevent a short circuit due to the contact between the gate electrode and the semiconductor layer at the time of being curved.

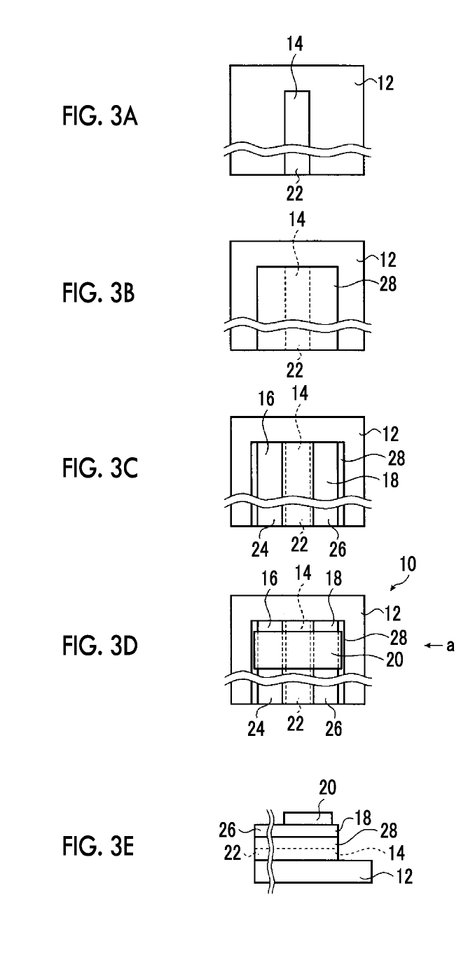

Next, each of the steps of the manufacturing method of a transistor will be described by using FIG. 3A to FIG. 3E.

FIG. 3A to FIG. 3D are schematic top views illustrating examples of a preferred embodiment of a manufacturing method of a thin film transistor, and FIG. 3E is a side view in which FIG. 3D is seen from an a direction.

[Substrate Preparing Step]

The substrate preparing step is a step of preparing the substrate 12 having insulating properties.

[Gate Electrode Forming Step]

As illustrated in FIG. 3A, the gate electrode forming step is a step of forming a wiring layer 22 to be connected to the gate electrode 14 and the gate electrode 14 on one main surface of the prepared substrate 12 by a method such as printing, photolithography, and plating. In the gate electrode forming step, a paint which becomes the formation material of the electrode is applied in a predetermined pattern by printing, and is cured, and thus, the gate electrode 14 and the wiring layer 22 are formed, as an example. Furthermore, in the illustrated example, the wiring layer 22 is integrally formed to the end side of the substrate 12 with the same thickness and the same width as those of the gate electrode 14.

[Insulating Film Forming Step]

As illustrated in FIG. 3B, the insulating film forming step is a step of forming the insulating film 28 on the substrate 12 on which the gate electrode 14 and the wiring layer 22 are formed to cover at least a part of the substrate 12, and the gate electrode 14 and the wiring layer 22.

As described above, the insulating film 28 can be formed according to a method which is suitably selected from a wet method such as a printing method and a coating method, a physical method such as a vacuum vapor deposition method, a sputtering method, and an ion plating method, a chemical method such as CVD and a plasma CVD method, and the like, in consideration of suitability with respect to a material to be used.

[Source and Drain Electrodes Forming Step]

As illustrated in FIG. 3C, the source and drain electrodes forming step is a step of forming the source electrode 16 and the drain electrode 18 on the insulating film 28. In the source and drain electrodes forming step, the source electrode 16 and the drain electrode 18 are formed to sandwich the gate electrode 14 therebetween in the surface direction of the substrate 12.

In the example illustrated in FIG. 3C, each of a wiring layer 24 to be connected to the source electrode 16 and a wiring layer 26 to be connected to the drain electrode 18 is integrally formed with the electrode. Furthermore, in the illustrated example, the wiring layer 24 is integrally formed to the end side of the substrate 12 with the same thickness and the same width as those of the source electrode 16, and the wiring layer 26 is integrally formed to the end side of the substrate 12 with the same thickness and the same width as those of the drain electrode 18.

[Semiconductor Layer Forming Step]

As illustrated in FIG. 3D, the semiconductor layer forming step is a step of preparing the thin film transistor 10 by placing the semiconductor layer 20 on the upper surfaces of the source electrode 16 and the drain electrode 18.

The semiconductor layer forming step includes the semiconductor layer preparing step of forming the semiconductor layer member on the support, and the semiconductor layer laminating step of placing the semiconductor layer member on the upper surfaces of the source electrode and the drain electrode, as a preferred aspect.

(Semiconductor Layer Preparing Step)

The semiconductor layer preparing step is a step of forming a member (a semiconductor layer member) which becomes the semiconductor layer on a support formed of a resin, glass, or the like, in advance, by a known method such as coating and transfer.

In the semiconductor layer preparing step, it is preferable that the surface of the semiconductor layer member is smoothly formed.

(Semiconductor Layer Laminating Step)

The semiconductor layer laminating step is a step of forming the semiconductor layer 20 by peeling off the semiconductor layer member prepared in the semiconductor layer preparing step from the support or by placing the semiconductor layer member on the upper surfaces of the source electrode 16 and the drain electrode 18 in a state of being integrated with the support.

Even in a case where the semiconductor layer member is laminated by being peeled off from the support, it is preferable that the upper surface side of the semiconductor layer member is placed towards the source electrode 16 and the drain electrode 18.

As described above, the transistor and the manufacturing method of a transistor of the present invention have been described in detail, but the present invention is not limited to the examples described above, and it is apparent that various improvements or changes are performed in a range not departing from the scope of the present invention.

### EXAMPLES

Hereinafter, the present invention will be described in more detail on the basis of examples. Materials, use amounts, ratios, treatment contents, treatment sequences, and the like of the following examples are able to be suitably changed unless the changes cause deviance from the gist of the present invention. Accordingly, the range of the present invention will not be restrictively interpreted by the following examples.

### Example 1

<Preparation of Thin Film Transistor>

Alkali-free glass having a thickness of 0.7 mm and a size of 50 mm×50 mm (EAGLE, manufactured by Corning Incorporated) was used as the substrate, and the gate electrode, the insulating film, the source electrode and the drain electrode, and the semiconductor layer were sequentially deposited on the surface of the substrate, and thus, the thin film transistor 10 having a configuration illustrated in FIG. 3D and FIG. 3E was prepared as Example 1.

(Gate Electrode Forming Step)

The gate electrode 14 and the wiring layer 22 were formed on the surface of the alkali-free glass described above by being patterned by a photoresist and etching.

Ag was used as the material of the gate electrode 14 and the wiring layer 22.

The size of the gate electrode 14 was set to a width of 200 μm×a depth of 1 mm, and the thickness of the gate electrode 14 was set to 100 nm.

The thickness of the wiring layer 22 was 100 nm, the width of the wiring layer 22 was set to 200 μm, and the wiring layer 22 was formed from the end surface of the gate electrode 14 to the end side of the substrate 12.

Furthermore, in the size of the electrode, an arrangement direction of the electrode is a width, and a direction orthogonal to the arrangement direction is a depth.

(Insulating Film Forming Step)

Next, the insulating film 28 formed of SiO₂ was formed by vapor deposition to cover at least a part of the substrate 12, and the gate electrode 14 and the wiring layer 22. The vapor deposition was performed by a known method.

The thickness of the insulating film 28 on the gate electrode 14 was set to 300 nm. In addition, the size of the insulating film 28 was set to a sufficient size such that the source electrode 16 and the drain electrode 18 described below were formed on the insulating film 28.

(Source and Drain Electrodes Forming Step)

Next, the source electrode 16 and the drain electrode 18, and the wiring layers 24 and 26 to be respectively connected to the electrodes were formed on the insulating film 28 by being patterned by a photoresist and etching.

The size of each of the source electrode 16 and the drain electrode 18 was set to a width of 200 μm×a depth of 1 mm, and the thickness of each of the source electrode 16 and the drain electrode 18 was set to 300 nm. In addition, the distance between the source electrode 16 and the drain electrode 18 was set to 200 μm.

That is, a configuration was adopted in which in the source electrode 16, the gate electrode 14, and the drain electrode 18, the width of the arrangement direction of each of the source electrode 16, the gate electrode 14, and the drain electrode 18 was set to 200 μm, and the gate electrode 14 was formed between the source electrode 16 and the drain electrode 18 in the surface direction of the substrate 12.

In addition, the height of the gap region G is 300 nm. Accordingly, the ratio of the thickness of the insulating film to the height of the gap region G is 1.

The thicknesses of the wiring layers 24 and 26 were set to 100 nm, the widths of the wiring layers 24 and 26 were set to 200 μm, and the wiring layers 24 and 26 were formed from the end surface of the electrode to the end side of the substrate 12.

(Semiconductor Layer Preparing Step)

A semiconductor layer member which became the semiconductor layer 20 was formed on a silicon substrate in advance, by coating and drying.

TIPS pentacene was used as the material of the semiconductor layer 20.

The thickness of the semiconductor layer 20 was set to 0.1 μm, and the size of the semiconductor layer 20 was set to a width of 600 μm×and a depth of 1 mm

(Semiconductor Layer Laminating Step)

The semiconductor layer member was peeled off from the support, and was placed on the upper surfaces of the source electrode 16 and the drain electrode 18 by allowing a width direction of 600 μm to be coincident with the arrangement direction of the electrode, and thus, the thin film transistor 10 was prepared.

(Evaluation)

<Bending Resistance>

First, end portions of the wiring layers 22, 24, and 26 of the prepared thin film transistor 10 were respectively clipped with alligator clips, and were connected to a source measure unit (manufactured by TEKTRONIX, INC.), and measurement of semiconductor properties was performed.

Next, in a state where the thin film transistor 10 was bent at a curvature radius of 10 mm, the measurement of the semiconductor properties was performed as described above. Further, in a state where the thin film transistor 10 returned to the original smooth shape after being bent, the measurement of the semiconductor properties was performed, and evaluation was performed on the basis of the following standards.

A: Even in the state where the thin film transistor 10 was bent and in the state where the thin film transistor 10 returned to the smooth shape after being bent, the semiconductor properties were rarely changed, and a normal operation was performed.

B: In the state where the thin film transistor 10 was bent, the semiconductor properties were degraded, and a normal operation was not performed as a semiconductor.

C: Even in the state where the thin film transistor 10 was bent and in the state where the thin film transistor 10 returned to the smooth shape after being bent, the semiconductor properties were degraded, and a normal operation was not performed.

As a result of the evaluation, evaluation A was obtained.

<Withstand Voltage Properties>

The thin film transistor 10 was connected to the source measure unit described above, a high voltage was applied to the gate electrode 14, and the presence or absence of a discharge was visually observed.

Evaluation was performed on the basis of the following standards.

A: Even in a case where a voltage of 40 V was applied, the discharge was not observed.

B: The discharge was not observed at a voltage of 10 V, but the discharge was observed at 40 V.

C; The discharge was observed at a voltage of 10 V.

As a result of the evaluation, evaluation A was obtained.

### Examples 2 to 5

The thin film transistor 10 was prepared by the same method as that in Example 1 except that the thickness of the insulating film was changed to a thickness shown in Table 1, and the evaluation of the bending resistance and the withstand voltage properties was performed.

The results are shown in Table 1.

### Comparative Example 1

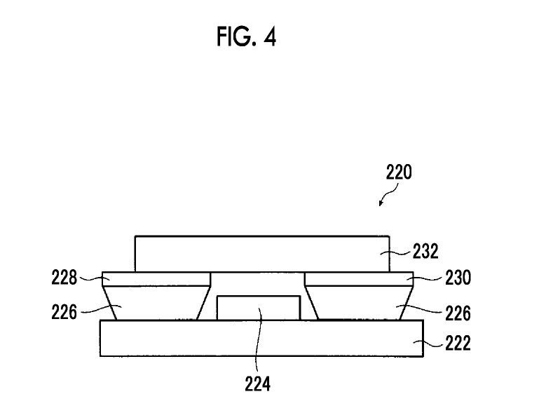

A thin film transistor 220 illustrated in FIG. 4 was prepared as Comparative Example 1.

The thin film transistor 220 includes a substrate 222, two pedestals 226 having insulating properties which are formed on the surface of the substrate 222, a gate electrode 224 formed on the surface of the substrate 222 between the two pedestals 226, a source electrode 228 and a drain electrode 230 respectively formed on the pedestal 226, and a semiconductor layer 232 placed on upper surfaces of the source electrode 228 and the drain electrode 230.

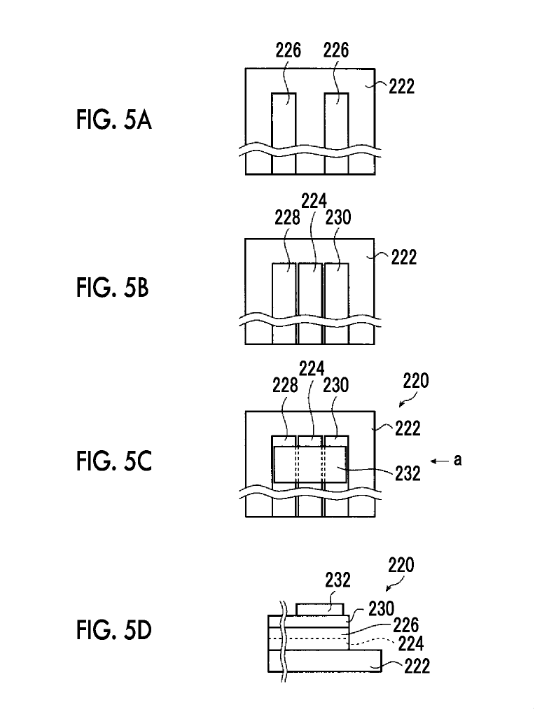

A preparation method of the thin film transistor 220 will be described by using FIG. 5A to FIG. 5D.

FIG. 5A to FIG. 5C are top views for illustrating the preparation method of the thin film transistor 220, and FIG. 5D is a side view in which FIG. 5C is seen from an a direction.

First, as illustrated in FIG. 5A, the two pedestals 226 are formed on the substrate 222 by a photoresist.

The same substrate as that of Example 1 was used as the substrate 222.

The material of the pedestal 226 was set to OFPR800 manufactured by TOKYO OHKA KOGYO CO., LTD., the width of the pedestal 226 was set to 200 μm, the thickness of the pedestal 226 was set to 300 nm, and a direction orthogonal to an arrangement direction of the pedestal 226 was set to a length of 20 mm from the end side of the substrate. In addition, a distance between the two pedestals 226 was set to 300 μm.

Next, the entire surface of the substrate 222 on which the two pedestals 226 were formed was deposited with Ag, and then, was patterned by being coated with a photoresist, and Ag was etched, and thus, as illustrated in FIG. 5B, the gate electrode 224, the source electrode 228, the drain electrode 230, and a wiring layer to be respectively connected to the electrodes were formed.

The size of the gate electrode 224 to be formed between the two pedestals 226 was set to 200 μm×1 mm, and the thickness of the gate electrode 224 was set to 100 nm.

In addition, the thickness of the source electrode 228 and the drain electrode 230 to be formed on the entire surface of the pedestal 226 was set to 100 nm.

The thickness of the wiring layer was set to 100 nm, the width of the wiring layer on the end side of the substrate was set to 200 μm, and the wiring layer was formed from the end surface of the electrode to the end side of the substrate 12.

Next, as illustrated in FIG. 5C and FIG. 5D, a semiconductor layer member was placed on the upper surfaces of the source electrode 228 and the drain electrode 230, and the semiconductor layer 232 was formed, and thus, the thin film transistor 220 was prepared.

Furthermore, the material and a formation method of the semiconductor layer 232 were identical to those of Example 1.

A distance between the gate electrode 224 and the semiconductor layer 232 of the thin film transistor 220, that is, a height of a gap region is 300 nm.

In the prepared thin film transistor 220, the evaluation of the bending resistance and the withstand voltage properties was performed by the same method as that in Example 1. The results are shown in Table 1.

### Comparative Example 2

The thin film transistor 220 was prepared by the same method as that in Comparative Example 1 except that the thickness of the pedestal was changed to 2,000 nm, and the evaluation of the bending resistance and the withstand voltage properties was performed.

The results are shown in Table 1.

TABLE 1

| | Thickness of | | Thickness of | | |
|---|---|---|---|---|---|
| | Insulating | Height of | Insulating | Evaluation | |
| | Film | Gap Region | Film/Height of | Bending | Withstand Voltage |
| | nm | nm | Gap Region | Resistance | Properties |
| Example 1 | 300 | 300 | 1 | A | A |
| Example 2 | 600 | 300 | 2 | A | A |
| Example 3 | 60 | 300 | 0.2 | A | A |
| Example 4 | 30 | 300 | 0.1 | A | B |
| Example 5 | 10 | 300 | 0.03 | B | B |
| Comparative | — | 300 | — | C | C |
| Example 1 | | | | | |
| Comparative | — | 2,000 | — | C | B |
| Example 2 | | | | | |

From Table 1, it is found that in Examples 1 to 5 where the insulating film is formed on the gate electrode side between the gate electrode and the semiconductor layer, and the gap region was formed between the semiconductor layer and the insulating film, in the direction perpendicular to the main surface of the substrate, the bending resistance and the withstand voltage properties are high, compared to Comparative Examples 1 and 2 where the insulating film is not provided between the gate electrode and the semiconductor layer.

In addition, from a comparison between Examples 1 to 4 and Example 5, it is found that it is preferable that the ratio of the thickness of the insulating film to the height of the gap region is greater than or equal to 0.1 from the viewpoint of the bending resistance.

In addition, from a comparison between Examples 1 to 3 and Examples 4 and 5, it is found that it is preferable that the thickness of the insulating film is greater than or equal to 50 nm from the viewpoint of the withstand voltage properties.

From the above description, the effect of the present invention is apparent.

### EXPLANATION OF REFERENCES

10, 40, 50, 60, 70, 220: thin film transistor
12, 222: substrate
14, 224: gate electrode
16, 72, 228: source electrode
18, 74, 230: drain electrode
20, 52, 232: semiconductor layer
22, 24, 26, 234: wiring layer
28, 42, 54, 76: insulating film

What is claimed is:

1. A transistor, comprising:
a substrate having insulating properties;
a source electrode and a drain electrode disposed in a surface direction of a main surface of the substrate by being separated from each other;
a gate electrode disposed between the source electrode and the drain electrode in the surface direction of the substrate;
a semiconductor layer disposed in contact with the source electrode and the drain electrode; and
an insulating film disposed between the gate electrode and the semiconductor layer in a direction perpendicular to the main surface of the substrate,
wherein a gap region is formed between the semiconductor layer and the insulating film.

2. The transistor according to claim 1,
wherein the gate electrode is formed on the substrate,
the insulating film is formed to cover at least a part of the substrate and the gate electrode,
the source electrode and the drain electrode are formed on the insulating film, and
the semiconductor layer is disposed to be in contact with upper surfaces of the source electrode and the drain electrode.

3. The transistor according to claim 1,
wherein the gap region is filled with at least one of a gas or a liquid.

4. The transistor according to claim 1,
wherein the gap region is filled with a liquid having insulating properties.

5. The transistor according to claim 1,
wherein the gap region is in vacuum.

6. The transistor according to claim 1,
wherein a ratio of a thickness of the insulating film to a height of the gap region is 0.01 to 100, in the direction perpendicular to the main surface of the substrate.

7. The transistor according to claim 2,
wherein a ratio of a thickness of the insulating film to a height of the gap region is 0.01 to 100, in the direction perpendicular to the main surface of the substrate.

8. The transistor according to claim 7,
wherein the gap region is filled with at least one of a gas or a liquid.

9. The transistor according to claim 7,
wherein the gap region is filled with a liquid having insulating properties.

10. The transistor according to claim 7,
wherein the gap region is in vacuum.

11. A manufacturing method of a transistor, comprising:
a substrate preparing step of preparing a substrate having insulating properties;
a gate electrode forming step of forming a gate electrode;
a source and drain electrodes forming step of forming a source electrode and a drain electrode;
an insulating film forming step of forming an insulating film; and
a semiconductor layer forming step of forming a semiconductor layer,
wherein the insulating film is formed on the gate electrode side between the gate electrode and the semiconductor layer, and a gap region is formed between the semiconductor layer and the insulating film, in a direction perpendicular to a main surface of the substrate.

12. A manufacturing method of a transistor, comprising:
a substrate preparing step of preparing a substrate having insulating properties;
a gate electrode forming step of forming a gate electrode on the substrate;
an insulating film forming step of forming an insulating film to cover at least a part of the substrate and the gate electrode;
a source and drain electrodes forming step of forming a source electrode and a drain electrode by separating the source electrode and the drain electrode from each other to sandwich the gate electrode therebetween in a surface direction of a main surface of the substrate such that a height from the substrate is higher than the insulating film; and
a semiconductor layer forming step of forming a semiconductor layer such that the semiconductor layer is in contact with the source electrode and the drain electrode, and a gap region is formed in at least a part between the semiconductor layer and the insulating film.

13. The manufacturing method of a transistor according to claim 12,
wherein the semiconductor layer forming step includes,
a semiconductor layer preparing step of forming a semiconductor layer member on a support, and
a semiconductor layer laminating step of placing the semiconductor layer member on upper surfaces of the source electrode and the drain electrode.

14. The manufacturing method of a transistor according to claim 13,
wherein in the semiconductor layer laminating step, a surface of the semiconductor layer member on a side to be placed on the upper surfaces of the source electrode and the drain electrode is a flat surface.
